(19) United States
(12) Patent Application Publication
(10) Pub. No.: US 2020/0176414 A1
(43) Pub. Date: Jun. 4, 2020

(54) JOINT DEVICE AND CONTROL METHOD FOR JOINT DEVICE

(71) Applicant: JTEKT CORPORATION, Osaka (JP)

(72) Inventors: Koichiro MATSUHISA, Toyota-shi (JP); Yoshinori IMOTO, Kariya-shi (JP)

(73) Assignee: JTEKT CORPORATION, Osaka (JP)

(21) Appl. No.: 16/693,476

(22) Filed: Nov. 25, 2019

(30) Foreign Application Priority Data
Dec. 3, 2018 (JP) 2018-226546
Jun. 13, 2019 (JP) 2019-110361

(51) Int. Cl. H01L 23/00

(52) U.S. Cl. CPC H01L 24/75; H01L 24/83; H01L 2224/75263; H01L 2224/8383; H01L 2224/759; H01L 2224/83224; H01L 2224/83237; H01L 2224/75252

(57) ABSTRACT

A joint device includes a regulation device, a heating device, and a transparent portion. The regulation device includes a support base that includes a placement surface, and a regulation member. The heating device applies heat for causing solid phase diffusion at a joint interface between the two metal members by radiating an electromagnetic beam to a beam irradiated region via the regulation member. The beam irradiated region is set on a surface of one of the two metal members that is farther from the placement surface while the regulation device regulates motion of the two metal members. The transparent portion is provided at least at a portion corresponding to the beam irradiated region of the metal member to which the electromagnetic beam is irradiated, to transmit the electromagnetic beam.

### INCORPORATION BY REFERENCE

The disclosure of Japanese Patent Application No. 2019-110361 filed on Jun. 13, 2019 including the specification, drawings and abstract is incorporated herein by reference in its entirety.

### BACKGROUND

### 1. Technical Field

The present disclosure relates to a joint device and a control method for the joint device.

### 2. Description of Related Art

There is known a technique of joining two metal members to each other by radiating laser light. For example, Japanese Patent No. 4894528 describes a joint method including superposing a terminal on a surface of a semiconductor element and wiring on each other via a joint material and pressing a joint portion between the terminal on the surface of the semiconductor element and the wiring using a pressurization nozzle in a tubular shape. In this state, laser light is radiated to a surface of the wiring through the inside of the pressurization nozzle to heat the joint portion between the terminal and the wiring to melt the joint material. The molten joint material forms a joint layer so that the terminal and the wiring are joined to each other.

### SUMMARY

In the joint method according to Japanese Patent No. 4894528, the pressurization nozzle in a tubular shape presses the peripheral edge portion of the joint portion between the terminal and the wiring, and does not press the entirety of the joint portion between the terminal and the wiring. A portion of the wiring corresponding to the joint portion is thermally expanded upon heating by irradiation with the laser light. At this time, a portion of the wiring pressed by the pressurization nozzle is kept in tight contact with the terminal via the joint material. However, a portion of the wiring not pressed by the pressurization nozzle may be warped toward the inside of the pressurization nozzle (the opposite side from the terminal) along with thermal expansion due to laser heating, depending on the thickness of the wiring etc. The portion of the wiring that has been warped may not be kept in tight contact with the terminal via the joint material. Therefore, the terminal and the wiring may not be joined to each other appropriately, and hence the joint strength between the terminal and the wiring may not be secured.

The present disclosure provides a joint device that can secure the joint strength between two metal members and a control method for the joint device.

A first aspect of the present disclosure provides a joint device. The joint device includes a regulation device, a heating device, and a transparent portion. The regulation device includes a support base and a regulation member. The support base includes a placement surface on which two metal members superposed on each other are placed. The regulation member regulates motion of the two metal members in a direction in which the two metal members are superposed on each other with the two metal members held between the placement surface and the regulation member. The heating device is configured to cause solid phase diffusion at a joint interface between the two metal members by radiating an electromagnetic beam to a beam irradiated region via the regulation member. The beam irradiated region is set on a surface of one of the two metal members that is farther from the placement surface while the regulation device regulates the motion of the two metal members. The transparent portion is provided at least at a portion corresponding to the beam irradiated region of the metal member to which the electromagnetic beam is irradiated.

With this configuration, the electromagnetic beam from the heating device passes through the transparent portion to irradiate the beam irradiated region that is set on the surface of the metal member that is farther from the placement surface. With the electromagnetic beam absorbed by the metal member that is farther from the placement surface, the metal member is heated, and the heat generated through the irradiation with the electromagnetic beam is transferred toward the metal member that is closer to the placement surface. Therefore, heat for causing solid phase diffusion at the joint interface (joint portion) between the two metal members can be applied by radiating the electromagnetic beam to the surface of the metal member that is farther from the placement surface. When the joint interface between the two metal members is heated and the metal members are thermally expanded, the joint interface is pressurized through the thermal expansion of the metal members, since the regulation device regulates the motion of the two metal members in the direction in which the metal members are superposed on each other. Consequently, the two metal members are joined to each other with the two metal members tightly contacting each other at the joint interface and with solid phase diffusion caused at the joint interface between the two metal members.

In order to radiate the electromagnetic beam to the beam irradiated region of the metal member that is disposed farther from the placement surface via the metal member, it is conceivable to adopt a configuration in which a hole that simply allows passage of the electromagnetic beam, for example, is provided as the regulation member in place of the transparent portion that transmits the electromagnetic beam. In this case, the hole of the regulation member corresponds to the beam irradiated region of the regulation member disposed farther from the placement surface. Therefore, the portion corresponding to the beam irradiated region of the metal member disposed farther from the placement surface may be warped toward the inside of the hole of the regulation member along with heating due to irradiation with the electromagnetic beam, depending on the thickness of the metal member that is disposed farther from the placement surface etc. In the case where the metal member is warped in this manner, the two metal members are not appropriately brought into tight contact with each other or pressurized at the joint interface, which makes it difficult to cause diffusion (solid phase diffusion) of atoms at the joint interface between the two metal members. Thus, the joint strength between the two metal members may not be secured.

In this respect, with the joint device described above, the transparent portion regulates deformation of the portion corresponding to the beam irradiated region of the metal member disposed farther from the placement surface toward the opposite side from the placement surface. Therefore, a warp of the portion corresponding to the beam irradiated region of the metal member toward the opposite side from the placement surface is suppressed in the case where the metal member disposed farther from the placement surface is heated through irradiation with the electromagnetic beam. Thus, with the pressure that is generated along with thermal expansion of the metal member appropriately acting on the joint interface between the two metal members, atoms appropriately diffuse at the joint interface between the two metal members. Consequently, the joint strength between the two metal members is secured.

In the joint device described above, the regulation device may be configured to regulate the motion of the two metal members in the direction in which the two metal members are superposed on each other without pressing the superposed two metal members against each other.

With this configuration, the two metal members can be joined to each other, without pressurizing the joint interface from the outside of the metal members, by utilizing a pressure due to thermal expansion of the metal members. Therefore, there is no need for a pressurization device that pressurizes the joint interface from the outside of the metal members. The joint device described above is provided with the regulation device, rather than the pressurization device, and it is only necessary that the regulation device should regulate the motion of the two metal members in the direction in which the two metal members are superposed on each other. Thus, it is not necessary to generate a force for pressurizing the joint interface, unlike the pressurization device. Therefore, the regulation device can be reduced in size compared to a common pressurization device according to the related art. Thus, the size of the joint device can be reduced compared to the size of a joint device provided with the pressurization device.

In the joint device described above, the regulation member may include a first portion and a second portion. The first portion may contact a peripheral edge portion of the beam irradiated region on the surface of the one of the two metal members that is farther from the placement surface. The second portion may be the transparent portion, and may contact the beam irradiated region on the surface of the one of the two metal members that is farther from the placement surface.

With this configuration, the second portion of the regulation member as the transparent portion regulates deformation (a warp) of the portion corresponding to the beam irradiated region of the metal member disposed farther from the placement surface toward the opposite side from the placement surface. In addition, the first portion and the second portion can be formed of different materials, since the regulation member is divided into the first portion and the second portion.

In the joint device described above, the heating device may be configured to radiate a laser beam or an electron beam as the electromagnetic beam. Heat for causing solid phase diffusion at the joint interface between the two metal members can be applied by radiating the laser beam or the electron beam to the metal member that is farther from the placement surface as in this configuration. With the laser beam or the electron beam absorbed by the metal member that is farther from the placement surface, the metal member is heated, and the heat generated through the irradiation with the laser beam or the electron beam is transferred toward the metal member that is closer to the placement surface.

In the joint device described above, the two metal members may be a surface electrode of a semiconductor element provided on a substrate, or a metal film provided on a surface of the substrate, and a wiring member. As in this configuration, the surface electrode of the semiconductor element provided on the substrate, or the metal film that is formed on the surface of the substrate, and the wiring member can be joined to each other. In particular, in the case where the joint device executes a joint method that utilizes the solid phase diffusion described earlier, heat that is not enough to melt the two metal members is applied to the joint interface between the metal members. Therefore, the surface electrode of the semiconductor element, or the metal film that is formed on the surface of the substrate, and the wiring member can be joined to each other while suppressing a thermal effect on the semiconductor element or the substrate compared to a case where the two metal members are melted to be joined to each other, depending on the allowable temperature of the semiconductor element or the substrate.

In the joint device described above, the two metal members may be a semiconductor element provided on a substrate and a heat radiation member. As in this configuration, the semiconductor element that is provided on the substrate and the heat radiation member can be joined to each other. The semiconductor element and the heat radiation member can be joined to each other while suppressing a thermal effect on the semiconductor element or the substrate by executing a joint method that utilizes the solid phase diffusion described earlier.

The joint device described above may further include a detector and a controller. The detector may be configured to detect a state of the transparent portion. The controller may be configured to execute protection control determined in order to protect the transparent portion when it is determined that there is a possibility that an abnormality occurs in the transparent portion based on the state of the transparent portion that is detected through the detector.

With this configuration, the protection control that is determined in order to protect the transparent portion is executed when there is a possibility that an abnormality occurs in the transparent portion. Therefore, the transparent portion can be protected. The two metal members can be joined to each other with no abnormality present in the transparent portion. Therefore, the joint reliability of the joint device can be improved. Examples of the abnormality in the transparent portion include an event in which the electromagnetic beam is irradiated to the metal member and the metal member is melted and adheres to the transparent portion, and the electromagnetic beam is further irradiated to a portion of the transparent portion to which the molten metal has adhered so that the transparent portion is melted or cracked.

In the joint device described above, the detector may be a temperature sensor that detects a temperature of the beam irradiated region of the metal member to which the electromagnetic beam is irradiated, or in a vicinity of the beam irradiated region. The controller may be configured to lower an output of the heating device compared to a previous output of the heating device, or temporarily stop the output, as the protection control when it is determined that there is a possibility that an abnormality occurs in the transparent portion based on the temperature of the beam irradiated region, or in the vicinity of the beam irradiated region, and the temperature is detected through the temperature sensor.

The transparent portion contacts the beam irradiated region of the metal member to which the electromagnetic beam is irradiated. Therefore, heat generated at the portion corresponding to the beam irradiated region of the metal member is transmitted to the transparent portion. Thus, the transparent portion may be affected by the heat to be damaged along with heating of the metal member, depending on the irradiation power of the electromagnetic beam.

In addition, when the portion corresponding to the beam irradiated region of the metal member that is disposed farther from the placement surface is urged to be deformed toward the opposite side from the placement surface along with thermal expansion due to heating through irradiation with the electromagnetic beam, such deformation is regulated by the transparent portion. Therefore, the force of the metal member to deform may act on the transparent portion to damage the transparent portion.

In this respect, with the joint device described above, the output of the heating device is lowered compared to a previous output of the heating device, or temporarily stopped, as the protection control for the transparent portion when there is a possibility that an abnormality occurs in the transparent portion, that is, the transparent portion is damaged because of heating of the metal member or deformation of the metal member. Therefore, the temperature rise of the metal member and hence deformation of the metal member are suppressed. The transparent portion can be protected since damage to the metal member is suppressed.

In the joint device described above, the detector may be a pressure sensor provided in the support base at a position corresponding to the beam irradiated region of the metal member to which the electromagnetic beam is irradiated, and configured to detect a pressure in a direction that crosses the placement surface. The controller may be configured to lower an output of the heating device compared to a previous output of the heating device, or temporarily stop the output, as the protection control when it is determined that there is a possibility that an abnormality occurs in the transparent portion based on the pressure detected through the pressure sensor.

When the portion corresponding to the beam irradiated region of the metal member that is disposed farther from the placement surface is urged to be deformed toward the opposite side from the placement surface along with thermal expansion due to heating through irradiation with the electromagnetic beam, the force of the metal member to deform may act on the transparent portion to damage the transparent portion. The force of the metal member to deform also acts on the placement surface as a reaction, and therefore it is possible to determine whether there is a possibility that an abnormality occurs in the transparent portion based on the pressure detected through the pressure sensor.

With the joint device described above, the output of the heating device is lowered compared to the previous output of the heating device, or temporarily stopped, as the protection control for the transparent portion when there is a possibility that an abnormality occurs in the transparent portion, that is, the transparent portion is damaged because of heating of the metal member or deformation of the metal member. Therefore, the temperature rise of the metal member and hence deformation of the metal member are suppressed. The transparent portion can be protected since damage to the metal member is suppressed.

A second aspect of the present disclosure provides a control method for a joint device. The joint device includes a regulation device, a heating device, a transparent portion, a detector, and a controller. The regulation device includes a support base and a regulation member. The support base includes a placement surface on which two metal members superposed on each other are placed. The regulation member is configured to regulate motion of the two metal members in a direction in which the two metal members are superposed on each other with the two metal members held between the placement surface and the regulation member. The heating device is configured to apply heat for causing solid phase diffusion at a joint interface between the two metal members by radiating an electromagnetic beam to a beam irradiated region via the regulation member. The beam irradiated region is a region set on a surface of one of the two metal members that is farther from the placement surface while the regulation device regulates motion of the two metal members. The transparent portion is provided at least at a portion corresponding to the beam irradiated region of the metal member to which the electromagnetic beam is irradiated, to transmit the electromagnetic beam. The detector is configured to detect a state of the transparent portion. The control method includes: determining, by the controller, that there is a possibility that an abnormality occurs in the transparent portion based on the state of the transparent portion detected through the detector; and executing protection control, by the controller, when the controller determines that there is a possibility that the abnormality occurs. The protection control is determined in order to protect the transparent portion.

With the joint device according to the present disclosure, the joint strength between the two metal members can be secured.

### BRIEF DESCRIPTION OF THE DRAWINGS

Features, advantages, and technical and industrial significance of exemplary embodiments of the disclosure will be described below with reference to the accompanying drawings, in which like numerals denote like elements, and wherein:

FIG. 1 is a front view of a semiconductor module that is a joint body formed by a joint device according to a first embodiment joining two parts to each other;

FIG. 2 is a diagram illustrating a schematic configuration of the joint device according to the first embodiment;

FIG. 3 is a sectional view of an essential portion of the joint device according to the first embodiment, illustrating a state in which a wiring member is heated from the surface thereof;

FIG. 4 is a graph illustrating the relationship between the temperature of a joint interface between two metal members and the joint rate between the two metal members according to the first embodiment;

FIG. 5 is a graph illustrating the relationship between the irradiation conditions (irradiation power and irradiation time) for laser light and the temperature of the joint interface between the two metal members according to the first embodiment;

FIG. 6 is a two-dimensional model illustrating the flow of atoms at the joint interface between the two metal members according to the first embodiment;

FIG. 7 is a sectional view of an essential portion of a joint device according to a comparative example, illustrating a state in which a wiring member is warped along with laser heating;

FIG. 8 is a sectional view of an essential portion of a joint device according to another embodiment;

FIG. 9 is a diagram illustrating a schematic configuration of a joint device according to a second embodiment;

FIG. 10 is a diagram illustrating the joint device according to the second embodiment, illustrating an example of a configuration for determining an abnormality in a second portion of a regulation member;

FIG. 11 is a diagram illustrating the joint device according to the second embodiment, illustrating an example of a configuration for determining an abnormality in the second portion of the regulation member;

FIG. 12A is a graph illustrating an example of the mode of adjusting the output of a laser device in the case where an abnormality in the second portion of the regulation member is detected in the second embodiment;

FIG. 12B is a graph illustrating an example of the mode of adjusting the output of the laser device in the case where an abnormality in the second portion of the regulation member is detected in the second embodiment;

FIG. 13 is a diagram illustrating the joint device according to the second embodiment, illustrating an example of a configuration for executing protection control for protecting the second portion of the regulation member;

FIG. 14 is a diagram illustrating the joint device according to the second embodiment, illustrating an example of a configuration for executing protection control for protecting the second portion of the regulation member; and

FIG. 15 is a diagram illustrating the joint device according to the second embodiment, illustrating an example of a configuration for executing protection control for protecting the second portion of the regulation member.

### DETAILED DESCRIPTION OF EMBODIMENTS

### First Embodiment

A joint device according to a first embodiment will be described below. The joint device is a device that joins two parts that include metal or a metal portion using laser light (a laser beam) as an electromagnetic beam.

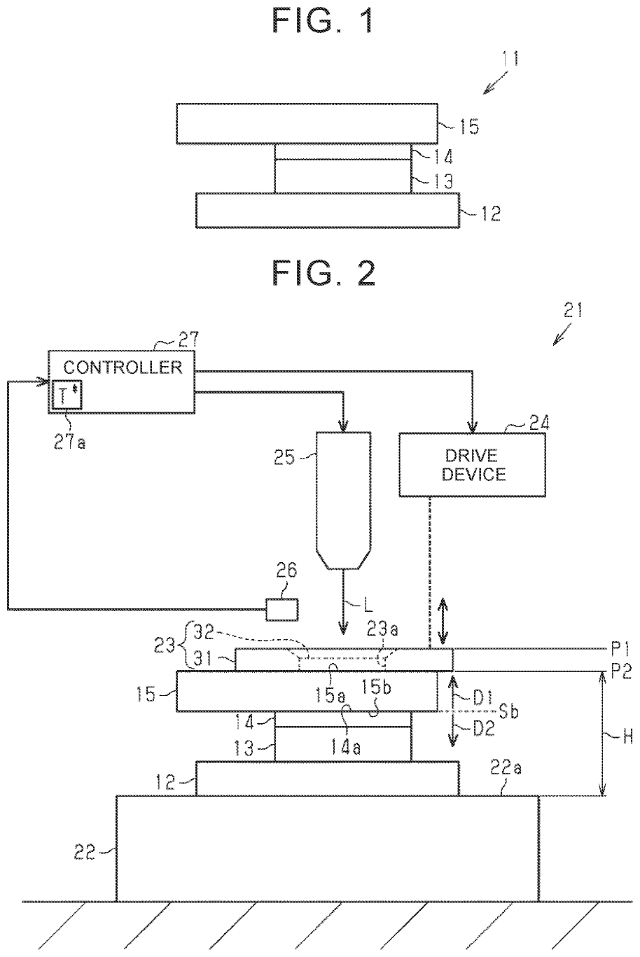

First, an example of a joint body formed by joining two parts to each other will be described. As illustrated in FIG. 1, a semiconductor module 11 as a joint body is formed by joining a surface electrode 14 of a semiconductor element 13, which is provided on a substrate 12, and a wiring member 15 to each other. The surface electrode 14 is a metal member formed from gold (Au) in a flat plate shape or a thin film shape. The wiring member 15 is a metal member such as a bus bar or a lead frame formed from copper (Cu) in a flat plate shape. The thickness of the wiring member 15 is larger than the thickness of the surface electrode 14.

The surface electrode 14 and the wiring member 15 are joined to each other through solid phase diffusion welding. The solid phase diffusion welding refers to a joint method including causing two base materials (here, the surface electrode 14 and the wiring member 15) to tightly contact each other and pressurizing the base materials to such a degree as to cause as little plastic deformation as possible at a temperature of the melting point of the base materials or less to join the base materials to each other utilizing diffusion of atoms caused between the respective joint surfaces thereof.

Next, a joint device will be described. As illustrated in FIG. 2, a joint device 21 has a support base 22, a regulation member 23, a drive device 24, a laser device 25 that serves as a heating device, a temperature sensor 26, and a controller 27.

The support base 22 has a placement surface 22a on which the substrate 12 and the wiring member 15 are to be placed. The substrate 12 is placed on the placement surface 22a with the semiconductor element 13 facing up (opposite side from the placement surface 22a). The wiring member 15 is superposed on the surface electrode 14 of the semiconductor element 13.

The regulation member 23 is formed in a flat plate shape. The regulation member 23 extends in parallel with the placement surface 22a of the support base 22. The regulation member 23 has a first portion 31 and a second portion 32.

The first portion 31 is formed in a flat plate shape from a metal material such as carbon steel or stainless steel. The first portion 31 is provided with a hole 23a that penetrates the first portion 31 in the thickness direction (up-down direction in FIG. 2). A tapered surface is provided at the inner peripheral edge of the opening portion of the hole 23a of the first portion 31 on the opposite side (upper side in FIG. 2) from the placement surface 22a. The tapered surface becomes larger in diameter toward the opposite side from the placement surface 22a.

The second portion 32 is provided inside the hole 23a of the first portion 31. The second portion 32 blocks the opening portion of the hole 23a on the side (lower side in FIG. 2) of the placement surface 22a. The second portion 32 is formed in a flat plate shape from a material that transmits laser light. The examples of the material include sapphire, diamond, calcium fluoride, silicon carbide (SiC), silicon (Si), and quartz (SiO₂). The thickness of the second portion 32 is set to be smaller than the thickness of the first portion 31. The bottom surface of the second portion 32 and the bottom surface of the first portion 31 are flush with each other (without a level difference therebetween). The second portion 32 corresponds to a transparent portion that transmits an electromagnetic beam.

The regulation member 23 is provided so as to be movable along a direction that is orthogonal to the placement surface 22a. The regulation member 23 is movable between an initial position P1 and a regulation position P2. The initial position P1 is higher than a height H of the upper surface of the wiring member 15 with reference to the placement surface 22a when the substrate 12 and the wiring member 15 are placed on the placement surface 22a as superposed on each other. The regulation position P2 is about as high as the height H with reference to the placement surface 22a when the substrate 12 and the wiring member 15 are placed on the placement surface 22a as superposed on each other. In FIG. 2, the initial position P1 and the regulation position P2 indicate the position of the lower surface (a surface on the placement surface 22a side) of the regulation member 23.

The regulation member 23 and the placement surface 22a of the support base 22 cooperate with each other to constitute a regulation device that regulates motion of two metal members (the wiring member 15 and the surface electrode 14 of the semiconductor element 13 that is provided on the substrate 12) in a direction (a direction that is orthogonal to the placement surface 22a) in which the metal members are superposed on each other without pressing the metal members against each other.

The drive device 24 moves the regulation member 23 along a direction that is orthogonal to the placement surface 22a. The drive device 24 has a drive source such as a motor or a cylinder, and a transfer mechanism that transfers power generated by the drive source to the regulation member 23. In FIG. 2, the transfer of power from the drive device 24 to the regulation member 23 is indicated by the dashed line. The drive device 24 also has a fixing mechanism that fixes the regulation member 23 at the regulation position P2 when the regulation member 23 is moved from the initial position P1 to the regulation position P2. A brake mechanism or a lock mechanism that regulates motion of the drive source or the transfer mechanism mentioned earlier, for example, is adopted as the fixing mechanism.

The laser device 25 radiates laser light L to the surface of the wiring member 15 via the hole 23a of the first portion 31 and the second portion 32 of the regulation member 23. The temperature sensor 26 detects the surface temperature of a laser irradiated region 15a, which is a region of the surface of the wiring member 15 to which the laser light L is irradiated (a region exposed from the hole 23a via the second portion 32 of the regulation member 23), in a non-contact manner. The laser irradiated region 15a corresponds to a beam irradiated region to which an electromagnetic beam is irradiated.

The controller 27 controls operation of the drive device 24 and the laser device 25. The controller 27 moves the regulation member 23 between the initial position P1 and the regulation position P2 through the drive device 24. In addition, the controller 27 estimates the temperature of a joint interface Sb between the surface electrode 14 and the wiring member 15 based on the surface temperature of the laser irradiated region 15a that is detected by the temperature sensor 26. The joint interface Sb refers to the boundary between two joint surfaces 14a, 15b that are respective portions of the surface electrode 14 and the wiring member 15 to be joined to each other. The joint surface 14a is the front surface (an interface on the wiring member 15 side) of the surface electrode 14. The joint surface 15b is the back surface (an interface on the surface electrode 14 side) of the wiring member 15. The controller 27 adjusts the output of the laser device 25 based on the temperature of the joint interface Sb.

The controller 27 has a storage device 27a. The storage device 27a stores a target temperature T* (joint temperature). The target temperature T* is a target value for the temperature of the joint interface Sb that is required to appropriately join the surface electrode 14 and the wiring member 15 to each other. The target temperature T* is set to a temperature in the range of equal to or more than the lower limit temperature (e.g. about 200° C. for copper), at which the metal members (the surface electrode 14 and the wiring member 15) to be joined can be joined to each other through solid phase diffusion welding, and equal to or less than the melting point of the metal members (the surface electrode 14 and the wiring member 15) to be joined.

The target temperature T* is set based on the relationship between the joint rate between the surface electrode 14 and the wiring member 15 and the temperature of the joint interface Sb. The joint rate refers to the rate between the true joint area, which is the area of a portion of the joint interface Sb that is actually joined, and an area obtained by summing the true joint area and the apparent joint area, which is the area of a portion of the joint interface Sb that is not actually joined. The relationship between the joint rate and the temperature of the joint interface Sb is calculated through experimentation or simulation. An example of the relationship between the temperature of the joint interface Sb and the joint rate is as follows.

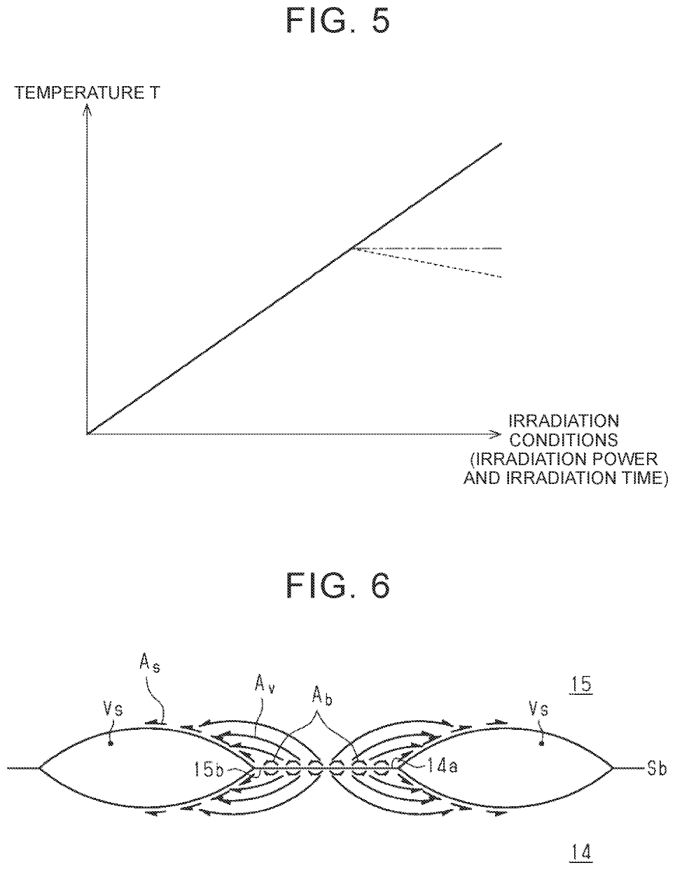

As indicated in the graph in FIG. 4, the joint rate S is gradually increased with respect to a rise in a temperature T of the joint interface Sb, and then the joint rate S becomes constant irrespective of the temperature T. A target joint rate S* is first determined, and the target temperature T* is determined based on the determined joint rate S*. The controller 27 controls the irradiation conditions (irradiation power and irradiation time) for the laser light L such that the temperature of the joint interface Sb coincides with the target temperature T*. An example of the relationship between the temperature T of the joint interface Sb and the irradiation conditions for the laser light L is as follows. As indicated in the graph in FIG. 5, for example, the temperature T of the joint interface Sb is raised as the irradiation power and the irradiation time of the laser light L, which are the irradiation conditions for the laser light L, are increased.

Manufacturing Method (Joint Method) for Joint Body

Next, a manufacturing method for the semiconductor module 11 will be described. It should be noted, however, that the substrate 12 on which the semiconductor element 13 is provided is prepared in advance. In addition, the regulation member 23 is held at the initial position P1 in the joint device 21. The substrate 12 is placed on the placement surface 22a with the semiconductor element 13 facing up. The wiring member 15 is superposed on the surface electrode 14 of the semiconductor element 13. Operation of the joint device 21 is started in this state.

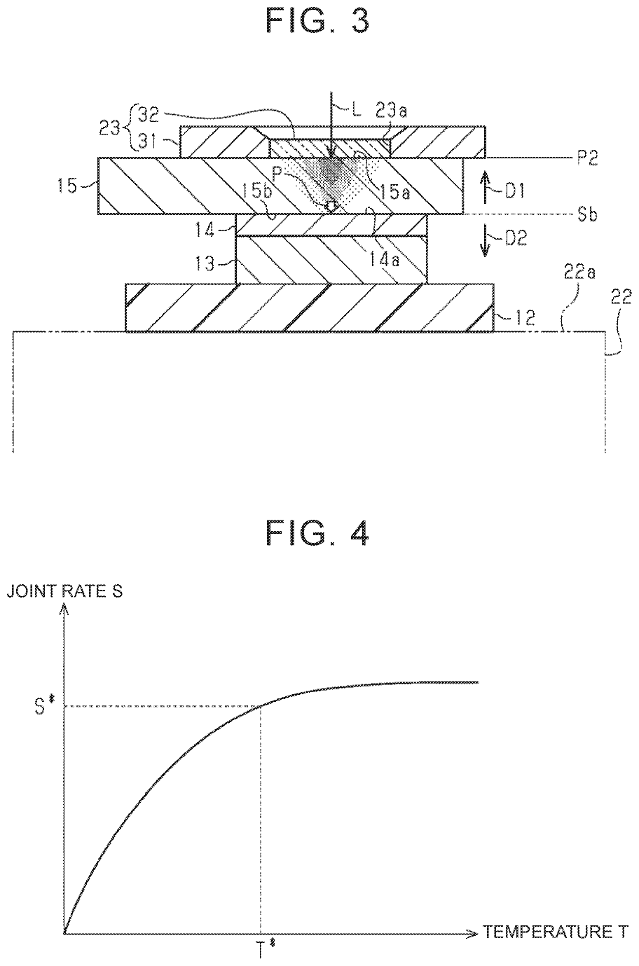

As illustrated in FIG. 3, the controller 27 moves the regulation member 23 from the initial position P1 to the regulation position P2 through the drive device 24. Consequently, the lower surface (a surface on the placement surface 22a side) of the regulation member 23 is maintained in contact with the upper surface (a surface on the opposite side from the surface electrode 14) of the wiring member 15. At this time, the wiring member 15 is not positively pressed against the surface electrode 14. Movement of the surface electrode 14 and the wiring member 15 in directions D1 and D2 (directions that are orthogonal to the placement surface 22a) away from each other is regulated with the substrate 12, on which the semiconductor element 13 is provided, and the wiring member 15 held between the placement surface 22a and the regulation member 23.

Next, the controller 27 irradiates the laser irradiated region 15a of the wiring member 15 with the laser light L through the laser device 25. When the laser light L is absorbed by the wiring member 15, the wiring member 15 is heated. As indicated by the shading in FIG. 3, heat generated through the irradiation with the laser light L is transferred from the front surface toward the back surface of the wiring member 15. The controller 27 irradiates the laser irradiated region 15a with the laser light L through the laser device 25 until the temperature T of the boundary between the joint surface 15b, which is the back surface of the wiring member 15, and the joint surface 14a, which is the front surface of the surface electrode 14, that is, the joint interface Sb, eventually reaches the target temperature T*. The shading in FIG. 3 indicates that a region at a higher temperature is more densely shaded (dotted), and that a region at a lower temperature is more sparsely shaded.

The wiring member 15 is thermally expanded along with a temperature rise due to heating. The regulation member 23 regulates deformation of the wiring member 15 toward the opposite side (upper side in FIG. 3) from the placement surface 22a. Thus, the wiring member 15 is expanded toward the surface electrode 14 (lower side in FIG. 3), toward which the wiring member 15 is most easily deformable. Therefore, a downward pressure P generated along with thermal expansion of the wiring member 15 in the thickness direction acts on the joint surface 14a that is the front surface of the surface electrode 14. Along with this pressurization, minute asperities on the joint surface 15b of the wiring member 15 and the joint surface 14a of the surface electrode 14 contact each other to be collapsed, which expedites tight contact between the joint surface 15b and the joint surface 14a.

As indicated by the two-dimensional model of the joint interface in FIG. 6, voids Vs are formed at the joint interface Sb that is the boundary between the joint surface 15b and the joint surface 14a immediately after the start of joint. When tight contact between the joint surface 15b and the joint surface 14a is expedited, diffusion of atoms (surface diffusion Aₛ, interface diffusion A_{b}, and volume diffusion Aᵥ) is caused at the joint interface Sb between the surface electrode 14 and the wiring member 15. The surface diffusion Aₛ refers to diffusion that uses the surface of the voids Vs as the path. The interface diffusion A_{b} refers to diffusion that uses the joint interface Sb as the path. The volume diffusion Aᵥ refers to diffusion that uses crystals (crystal lattices) as the path. The voids Vs at the joint interface Sb are contracted or eliminated through this diffusion (solid phase diffusion) of atoms and creep deformation in the vicinity of the joint interface Sb, which expedites joint between the joint surface 14a of the surface electrode 14 and the joint surface 15b of the wiring member 15. That is, as the voids Vs are contracted to be eliminated, the apparent joint surface, which is the area of a portion of the joint interface Sb that is not actually joined, is decreased, while the true joint area, which is the area of a portion of the joint interface Sb that is actually joined, is increased.

When the temperature of the joint interface Sb reaches the target temperature T*, the controller 27 continues this state for a predetermined heating time. Consequently, contraction and elimination of the voids Vs is expedited through creep deformation in the vicinity of the joint interface Sb and diffusion of atoms. That is, the joint rate S is increased along with the progress of contraction and elimination of the voids Vs, and reaches the target joint rate S* (joint strength). In the case where the target joint rate S* is “1 (maximum value)”, for example, the joint surface 14a of the surface electrode 14 and the joint surface 15b of the wiring member 15 are completely joined to each other over the entire target joint range on the joint surfaces 14a, 15b. The joint interface Sb present immediately after the start of joint has disappeared at a portion corresponding to the joint range in which the joint surfaces 14a, 15b are joined to each other.

### Comparative Example

Next, a comparative example in which a regulation member without the second portion 32 is adopted will be described.

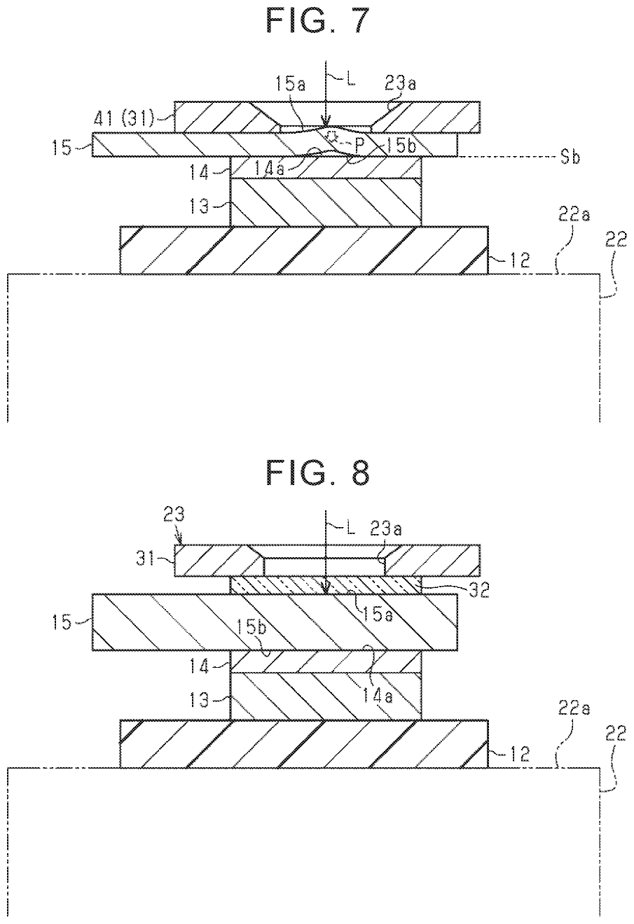

As illustrated in FIG. 7, a regulation member 41 according to the comparative example has only the first portion 31 of the regulation member 23 according to the present embodiment. When the surface electrode 14 and the wiring member 15 are to be joined to each other, the substrate 12 that has the semiconductor element 13, the wiring member 15, and the regulation member 41 are superposed in this order on the placement surface 22a of the support base 22. The laser irradiated region 15a of the wiring member 15 corresponds to the hole 23a of the regulation member 41. Therefore, the regulation member 41 does not contact the laser irradiated region 15a. The regulation member 41 contacts the peripheral edge portion of the laser irradiated region 15a of the wiring member 15. In this state, the laser light L is irradiated to the laser irradiated region 15a of the wiring member 15 via the hole 23a of the regulation member 41.

When the wiring member 15 is heated to be thermally expanded with the laser light L absorbed by the wiring member 15, a portion corresponding to the laser irradiated region 15a of the wiring member 15 may be warped inward (upward in FIG. 7) of the hole 23a of the regulation member 41 along with thermal expansion due to laser heating, depending on the thickness of the wiring member 15, etc. This is because deformation of the portion corresponding to the laser irradiated region 15a of the wiring member 15 toward the opposite side from the placement surface 22a is not regulated since such a portion corresponds to the hole 23a of the regulation member 41. A gap is occasionally formed between the portion corresponding to the laser irradiated region 15a of the wiring member 15 and the surface electrode 14 as the wiring member 15 is warped.

Therefore, when the wiring member 15 is warped, a pressurization force that acts on the joint surface 14a that is the front surface of the surface electrode 14, that is, a downward pressure P generated along with thermal expansion of the wiring member 15 in the thickness direction, is lowered. As a result, tight contact between the joint surface 15b of the wiring member 15 and the joint surface 14a of the surface electrode 14 is not expedited appropriately, and diffusion of atoms at the joint interface Sb between the surface electrode 14 and the wiring member 15 is less likely to be caused. Thus, the joint strength between the surface electrode 14 and the wiring member 15 may be lowered. The wiring member 15 is more likely to be warped as the wiring member 15 is thinner.

### Functions of Present Embodiment

In this respect, the regulation member 23 according to the present embodiment is provided with the second portion 32 that transmits the laser light L inside the hole 23a of the first portion 31. When the surface electrode 14 and the wiring member 15 are to be joined to each other, movement of the surface electrode 14 and the wiring member 15 in directions (up-down direction in FIG. 7) away from each other is regulated with the substrate 12, on which the semiconductor element 13 is provided, and the wiring member 15 held between the regulation member 23 and the placement surface 22a of the support base 22. At this time, the first portion 31 of the regulation member 23 is maintained in contact with the peripheral edge portion of the laser irradiated region 15a of the wiring member 15. In addition, the second portion 32 of the regulation member 23 is maintained in contact with the laser irradiated region 15a of the wiring member 15. In this state, the laser light L is irradiated to the laser irradiated region 15a of the wiring member 15 via the hole 23a of the first portion 31 and the second portion 32.

When the wiring member 15 is heated to be thermally expanded with the laser light L absorbed by the wiring member 15, a portion corresponding to the laser irradiated region 15a of the wiring member 15 is urged to be warped inward (upward in FIG. 3) of the hole 23a of the regulation member 41 along with thermal expansion due to laser heating, depending on the thickness of the wiring member 15, etc. However, the second portion 32 of the regulation member 23 regulates deformation of the portion corresponding to the laser irradiated region 15a of the wiring member 15 toward the opposite side (upper side in FIG. 3) from the placement surface 22a. That is, a warp of the portion corresponding to the laser irradiated region 15a of the wiring member 15 toward the opposite side from the surface electrode 14 and hence formation of a gap between the portion corresponding to the laser irradiated region 15a of the wiring member 15 and the surface electrode 14 are suppressed.

Therefore, the wiring member 15 is expanded toward the surface electrode 14 (lower side in FIG. 3), toward which the wiring member 15 is most easily deformable, and a downward pressure P generated along with thermal expansion of the wiring member 15 in the thickness direction appropriately acts on the joint surface 14a that is the front surface of the surface electrode 14. Along with this appropriate pressurization, tight contact between the joint surface 15b of the wiring member 15 and the joint surface 14a of the surface electrode 14 is expedited appropriately, and diffusion of atoms at the joint interface Sb between the surface electrode 14 and the wiring member 15 is caused appropriately. Thus, the joint strength between the surface electrode 14 and the wiring member 15 is secured.

### Effects of First Embodiment

Thus, according to the present embodiment, the following effects can be obtained.

(1) The first portion 31 of the regulation member 23 is provided with the hole 23a corresponding to the laser irradiated region 15a on the surface of the wiring member 15. The second portion 32 that transmits the laser light L is provided in the hole 23a of the first portion 31. Therefore, movement of the surface electrode 14 and the wiring member 15 in the directions D1 and D2 (direction of superposition) away from each other can be regulated without obstructing irradiation of the wiring member 15 with of the laser light L.

(2) The second portion 32 of the regulation member 23 regulates deformation of the portion corresponding to the laser irradiated region 15a of the wiring member 15 toward the opposite side from the surface electrode 14. Therefore, a warp of the portion corresponding to the laser irradiated region 15a of the wiring member 15 toward the opposite side from the surface electrode 14 is suppressed even in the case where the wiring member 15 is heated through irradiation with the laser light L. Thus, the pressure P generated along with thermal expansion of the wiring member 15 appropriately acts on the joint surface 14a of the surface electrode 14, as a result of which diffusion of atoms at the joint interface Sb between the surface electrode 14 and the wiring member 15 is caused appropriately. Consequently, the joint strength between the surface electrode 14 and the wiring member 15 is secured. The joint device 21 having the regulation member 23 is suitably used to join the wiring member 15 that is thinner and easily warped because of thermal expansion due to heating.

(3) The regulation member 23 is sectioned into the first portion 31 and the second portion 32. Therefore, the first portion 31 and the second portion 32 can be formed of different materials.

(4) The two metal members (the surface electrode 14 and the wiring member 15) that are superposed on each other are joined to each other utilizing a pressure due to thermal expansion of the metal members caused by applying heat to the joint interface Sb (joint portion) between the two metal members while regulating motion of the two metal members in the directions D1 and D2 away from each other. The two metal members can be joined to each other without positively pressurizing the joint interface Sb from the outside of the metal members. Therefore, there is no need for a pressurization device that pressurizes the joint interface Sb from the outside of the metal members. The joint device 21 is provided with the drive device 24 that moves the regulation member 23, rather than the pressurization device, and it is only necessary that the drive device 24 should generate a force that is just enough to move the regulation member 23. That is, there is no need for the drive device 24 to generate a large force for pressurizing the joint interface Sb, unlike the pressurization device. Therefore, the drive device 24 can be reduced in size compared to the pressurization device. Thus, the size of the joint device 21 can be reduced compared to the size of a joint device provided with the pressurization device.

(5) Movement of the two metal members (the surface electrode 14 and the wiring member 15) that are placed on the placement surface 22a as superposed on each other in the directions D1 and D2 away from each other can be regulated by only maintaining the regulation member 23 in contact with the surface of the metal member (15) that is positioned at the uppermost position. In addition, the configuration of the joint device 21 is not complicated.

### Second Embodiment

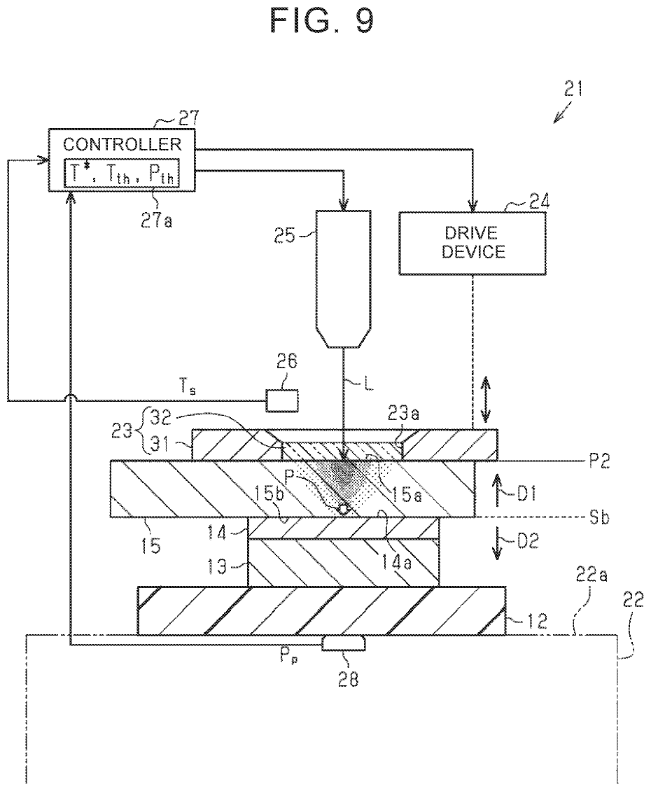

Next, a joint device according to a second embodiment will be described. As illustrated in FIG. 9, the joint device 21 basically has the same configuration as that according to the first embodiment described earlier. That is, the joint device 21 has a support base 22, a regulation member 23, a drive device 24, a laser device 25 that serves as a heating device, a temperature sensor 26, and a controller 27.

With the joint device 21 according to the first embodiment, the second portion 32 of the regulation member 23 suppresses a warp of the portion corresponding to the laser irradiated region 15a of the wiring member 15 toward the opposite side from the surface electrode 14 even in the case where the wiring member 15 is heated through irradiation with the laser light L. However, the joint device 21 according to the first embodiment has the following possibilities.

That is, while the wiring member 15 is heated with the laser light L, which is radiated via the second portion 32 of the regulation member 23, absorbed by the wiring member 15, the second portion 32 of the regulation member 23 contacts the laser irradiated region 15a of the wiring member 15. Therefore, heat generated at the portion corresponding to the laser irradiated region 15a of the wiring member 15 is transmitted to the second portion 32 of the regulation member 23. Thus, the second portion 32 of the regulation member 23 may be fused to be damaged, even if only slightly, along with laser heating of the wiring member 15, depending on the material that forms the second portion 32 or the irradiation power of the laser light L. Besides, there is a possibility that the wiring member 15 that is a copper material is melted and the molten copper adheres to the second portion 32 that is a transparent material, and it is conceivable that a portion of the second portion 32 to which the molten copper has adhered absorbs the laser light L so that the second portion 32 is melted or cracked by a thermal shock.

In addition, when the portion corresponding to the laser irradiated region 15a of the wiring member 15 is urged to be warped toward the opposite side from the surface electrode 14 along with thermal expansion due to laser heating, such a warp of the wiring member 15 is regulated by the second portion 32 of the regulation member 23. Therefore, the second portion 32 of the regulation member 23 may be cracked to be damaged with the warping force of the wiring member 15, which is generated along with laser heating of the wiring member 15, acting on the second portion 32 of the regulation member 23, depending on the degree to which the wiring member 15 is urged to be warped, the material that forms the second portion 32, etc.

Thus, the joint device 21 according to the present embodiment is provided with a protection control function for executing protection control for protecting the second portion 32 of the regulation member 23 when there is a possibility that an abnormality occurs in the second portion 32 of the regulation member 23.

The controller 27 determines whether there is a possibility that an abnormality occurs in the second portion 32 of the regulation member 23 using at least one of the following methods A1 to A4.

A1: The controller 27 monitors a surface temperature Tₛ of the laser irradiated region 15a of the wiring member 15, or in the vicinity thereof, when the wiring member 15 is laser-heated through the laser device 25. The controller 27 determines whether there is a possibility that an abnormality such as softening, deformation, or melting occurs in the second portion 32 of the regulation member 23 through a comparison between the surface temperature Tₛ of the laser irradiated region 15a that is detected through the temperature sensor 26 and a temperature threshold Tₜₕ stored in the storage device 27a of the controller 27. The temperature threshold Tₜₕ is set with reference to the softening point of the material that forms the second portion 32 of the regulation member 23. The softening point refers to the temperature at which a substance such as a resin or glass starts being softened to be deformed as the temperature rises. The controller 27 determines that there is no possibility that an abnormality occurs in the second portion 32 of the regulation member 23 when the surface temperature Tₛ of the laser irradiated region 15a that is detected through the temperature sensor 26 is less than the temperature threshold Tₜₕ. The controller 27 determines that there is a possibility that an abnormality occurs in the second portion 32 of the regulation member 23 when the surface temperature Tₛ of the laser irradiated region 15a detected through the temperature sensor 26 is equal to or more than the temperature threshold Tₜₕ. The controller 27 executes protection control determined in order to protect the second portion 32 of the regulation member 23 when it is determined that there is a possibility that an abnormality occurs in the second portion 32 of the regulation member 23.

A2: The joint device 21 has a pressure sensor 28. The pressure sensor 28 is provided on the support base 22. The pressure sensor 28 is provided at a position corresponding to the laser irradiated region 15a of the wiring member 15 with the substrate 12 on which the semiconductor element 13 is provided and the wiring member 15 held between the placement surface 22a of the support base 22 and the regulation member 23. It should be noted, however, that the pressure sensor 28 may be or may not be exposed from the placement surface 22a. The pressure sensor 28 detects a force in a direction that is orthogonal to the placement surface 22a of the support base 22. The controller 27 monitors a pressure Pₚ detected through the pressure sensor 28 when the wiring member 15 is laser-heated through the laser device 25. The controller 27 determines whether there is a possibility that an abnormality such as cracking occurs in the second portion 32 of the regulation member 23 through a comparison between the pressure Pₚ detected through the pressure sensor 28 and a pressure threshold Pₜₕ stored in the storage device 27a of the controller 27. The pressure threshold Pₜₕ is set through experimentation or simulation. The pressure threshold Pₜₕ is set with reference to the pressure at which an abnormality such as cracking occurs in the second portion 32 of the regulation member 23 when the wiring member 15 is laser-heated. The controller 27 determines that there is no possibility that an abnormality occurs in the second portion 32 of the regulation member 23 when the pressure Pₚ detected through the pressure sensor 28 is less than the pressure threshold Pₜₕ. The controller 27 determines that there is a possibility that an abnormality occurs in the second portion 32 of the regulation member 23 when the pressure Pₚ detected through the pressure sensor 28 is equal to or more than the pressure threshold Pₜₕ. The controller 27 executes protection control determined in order to protect the second portion 32 of the regulation member 23 when it is determined that there is a possibility that an abnormality occurs in the second portion 32 of the regulation member 23.

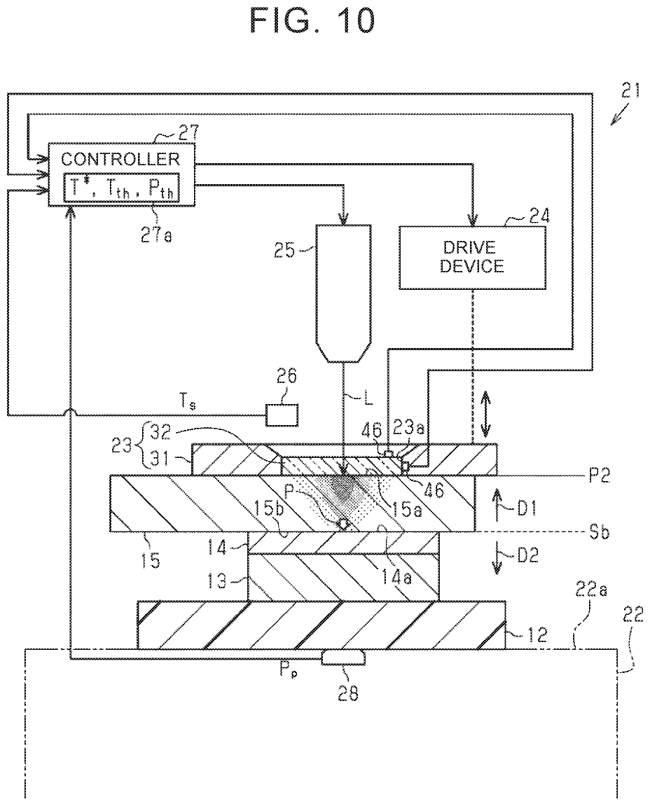

A3: As illustrated in FIG. 10, a strain gauge 46 is provided on at least one of the front surface and the outer peripheral surface of the second portion 32 of the regulation member 23. The controller 27 determines whether there is a possibility that an abnormality such as cracking occurs in the second portion 32 based on the amount of deformation of the second portion 32 due to thermal expansion due to heating in at least one of the radial direction and the thickness direction. The controller 27 makes a comparison between the amount of deformation of the second portion 32 detected through the strain gauge 46 and a deformation amount threshold stored in the storage device 27a, for example. The deformation amount threshold is set through experimentation or simulation. The deformation amount threshold is set with reference to the amount of deformation at the time when an abnormality such as cracking occurs in the second portion 32 of the regulation member 23 when the wiring member 15 is laser-heated. The controller 27 determines that there is no possibility that an abnormality occurs in the second portion 32 of the regulation member 23 when the amount of deformation of the second portion 32 detected through the strain gauge 46 is less than the deformation amount threshold. The controller 27 determines that there is a possibility that an abnormality occurs in the second portion 32 of the regulation member 23 when the amount of deformation of the second portion 32 detected through the strain gauge 46 is equal to or more than the deformation amount threshold. The controller 27 executes protection control determined in order to protect the second portion 32 of the regulation member 23 when it is determined that there is a possibility that an abnormality occurs in the second portion 32 of the regulation member 23.

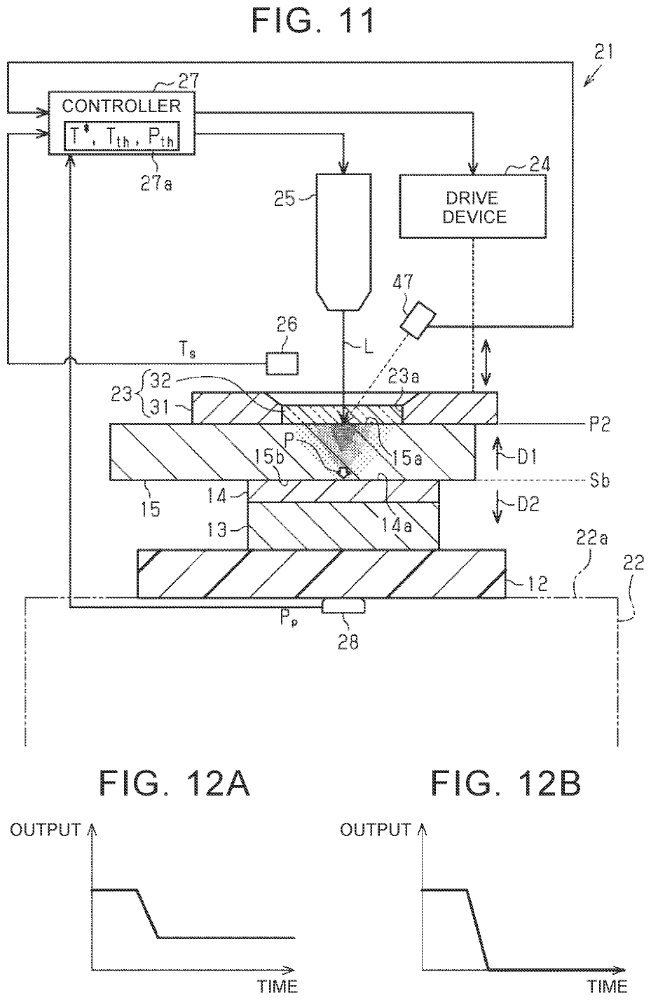

A4: As illustrated in FIG. 11, the joint device 21 is provided with an image capturing device 47 such as a camera. The controller 27 monitors the state of the second portion 32 of the regulation member 23 through the image capturing device 47. The controller 27 determines whether there is a possibility that an abnormality such as deformation, such as a warp, or fusing occurs in the second portion 32 based on captured image data on the second portion 32 acquired through the image capturing device 47. The controller 27 executes protection control determined in order to protect the second portion 32 of the regulation member 23 when it is determined that there is a possibility that an abnormality occurs in the second portion 32.

The controller 27 executes one of the following controls B1 to B5 as protection control for the second portion 32 of the regulation member 23.

B1: As illustrated in FIG. 12A, the output of the laser device 25 is lowered compared to the previous output of the laser device 25. The output of the laser device 25 is set to an output that is lower than the original output that is considered to be preferable in order to join the surface electrode 14 and the wiring member 15 to each other, for example. Consequently, the irradiation power of the laser light L is also lower than the original irradiation power. That is, the energy density of the laser light L to be absorbed by the wiring member 15 is lowered, and therefore the temperature rise of the wiring member 15 and hence a warp of the wiring member 15 are suppressed.

B2: As illustrated in FIG. 12B, the output of the laser device 25 is temporarily stopped. Consequently, the temperature rise of the wiring member 15 and hence a warp of the wiring member 15 are suppressed.

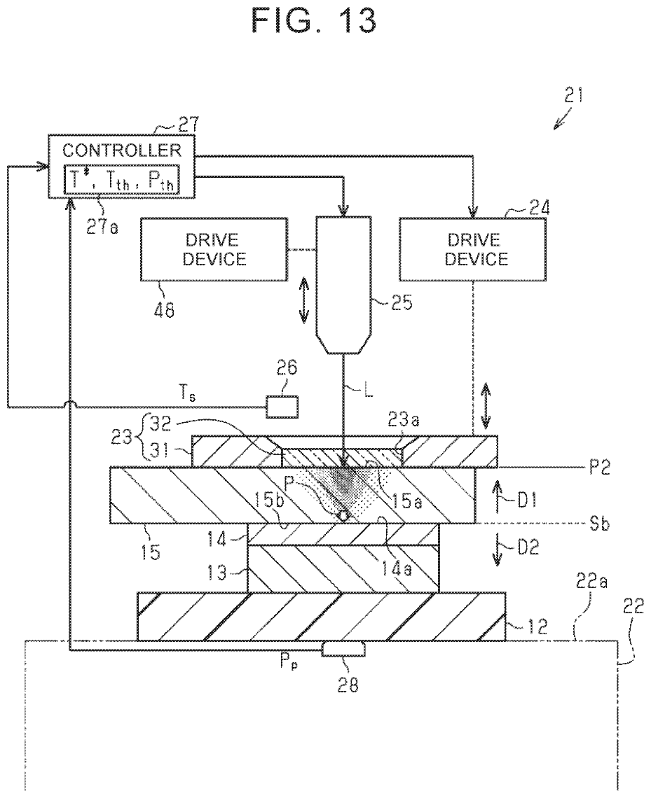

B3: As illustrated in FIG. 13, the laser device 25 is ascended or descended. The laser device 25 is moved in the direction away from the wiring member 15, or in the direction toward the wiring member 15, with reference to the original laser radiation position that is considered to be preferable in order to join the surface electrode 14 and the wiring member 15 to each other, for example. Consequently, the spot diameter of the laser light L is increased. In the case where the output of the laser device 25 is constant, the energy density of the laser light L is decreased as the spot diameter of the laser light L is increased. The energy density of the laser light L to be absorbed by the wiring member 15 is lowered, and therefore the temperature rise of the wiring member 15 and hence a warp of the wiring member 15 are suppressed. It should be noted, however, that in the case where this configuration is adopted, the laser device 25 is provided so as to be ascendable and descendible along a direction that is orthogonal to the placement surface 22a of the support base 22. In addition, the joint device 21 is provided with a drive device 48 that ascends and descends the laser device 25. In FIG. 13, the transfer of power from the drive device 48 to the laser device 25 is indicated by the dashed line. Alternatively, the support base 22 may be ascended and descended with respect to the reference position.

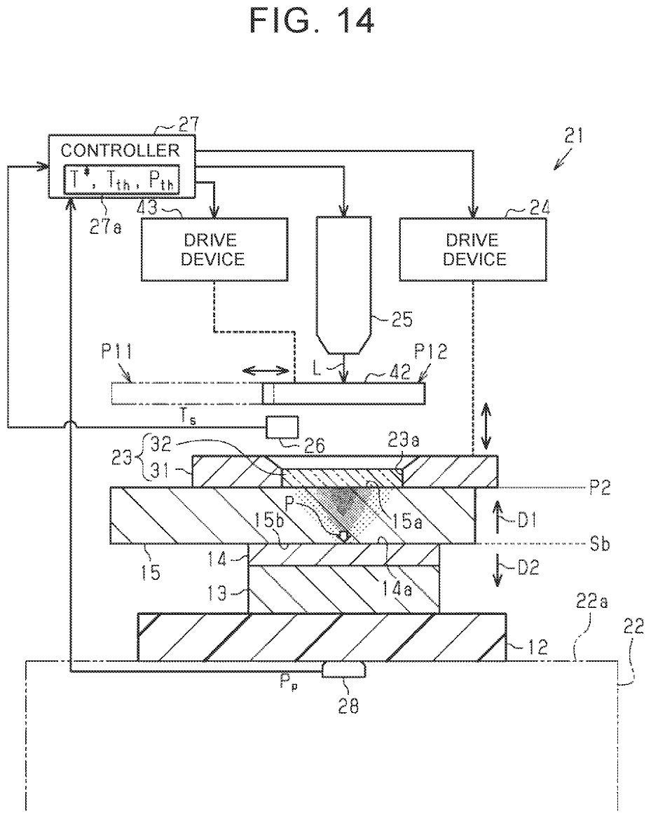

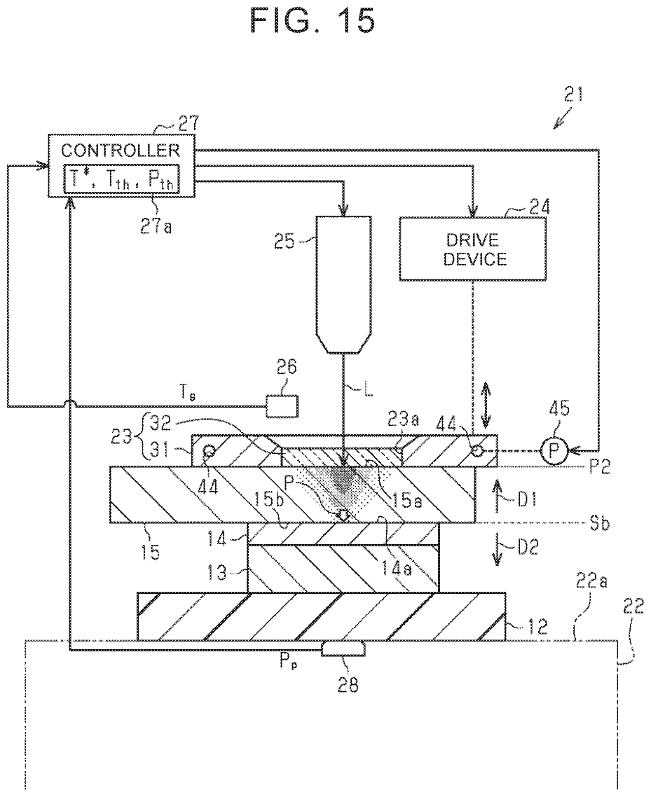

B4: As illustrated in FIG. 14, a blocking member 42 is interposed between the laser device 25 and the regulation member 23. With the laser light L blocked by the blocking member 42, the temperature rise of the wiring member 15 and hence a warp of the wiring member 15 are suppressed. It should be noted, however, that in the case where this configuration is adopted, the blocking member 42 is provided so as to be movable between a retracted position P11, which is indicated by the dashed double-short dashed line in FIG. 14, and a blocking position P12, which is indicated by the continuous line in FIG. 14. The retracted position P11 is a position at which the blocking member 42 is off the radiation path of the laser light L. The blocking position P12 is a position at which the blocking member 42 blocks the radiation path of the laser light L. The joint device 21 is also provided with a drive device 43 that drives the blocking member 42 between the retracted position P11 and the blocking position P12. In FIG. 14, the transfer of power from the drive device 43 to the blocking member 42 is indicated by the dashed line.

B5: As illustrated in FIG. 15, a cooling liquid is circulated in a flow path 44 provided in the regulation member 23. With the cooling liquid depriving the wiring member 15 of heat, the temperature rise of the wiring member 15 and hence a warp of the wiring member 15 are suppressed. It should be noted, however, that in the case where this configuration is adopted, the joint device 21 is provided with a pump 45 that circulates the cooling liquid in the flow path 44 of the regulation member 23. In FIG. 15, the supply of the cooling liquid from the pump 45 to the flow path 44 is indicated by the dashed line.

Thus, according to the second embodiment, the following effects can be obtained in addition to the effects (1) to (5) of the first embodiment described earlier.

(6) The state of the second portion 32 of the regulation member 23 that transmits the laser light L is monitored, and one of the controls B1 to B5 described earlier is executed as protection control for protecting the second portion 32 when it is determined that there is a possibility that an abnormality occurs in the second portion 32. Therefore, damage to the second portion 32 of the regulation member 23 due to laser heating is suppressed. Thus, the frequency of replacing the second portion 32 can be reduced. Since the protection control is executed before an abnormality occurs in the second portion 32, in addition, the surface electrode 14 and the wiring member 15 can be joined to each other with no abnormality present in the second portion 32. Therefore, the joint reliability of the joint device 21 is improved.

### Other Embodiments

The first and second embodiments may also be implemented in the following modified forms. The relationship between the temperature T of the joint interface Sb and the irradiation conditions (irradiation power and irradiation time) for the laser light L is not limited to the characteristic indicated by the graph in FIG. 5 described earlier. For example, the following two characteristics are conceivable. In the first characteristic, as indicated by the long dashed double-short dashed line in FIG. 5, the temperature T of the joint interface Sb is raised as the irradiation power and the irradiation time are increased, and then the temperature T is kept constant irrespective of the irradiation power and the irradiation time. In the second characteristic, as indicated by the dashed line in FIG. 5, the temperature T of the joint interface Sb is raised as the irradiation power and the irradiation time are increased, and thereafter the temperature T of the joint interface Sb is conversely lowered as the irradiation power and the irradiation time are increased. The relationship between the temperature T of the joint interface Sb and the irradiation power of the laser light L and the relationship between the temperature T of the joint interface Sb and the irradiation time of the laser light L may have different characteristics from each other.

The joint device 21 can join the surface electrode 14 and the wiring member 15 to each other. The joint device 21 can also join metal members having a variety of shapes to each other, such as joining a metal wire rod (wire) and a pad (electrode) on the substrate 12 to each other or joining a metal film formed on the surface of the substrate 12 by plating and the wiring member 15 to each other. The joint device 21 can also join the semiconductor element 13 as a metal member provided on the substrate 12 and a heat radiation member (heat sink) as a metal member to each other. The semiconductor element and the heat radiation member can be joined to each other while suppressing a thermal effect on the semiconductor element 13 or the substrate 12 by executing a joint method that utilizes solid phase diffusion.

The metal materials to be joined may be gold or copper. Further, the metal materials may be a variety of metal materials such as aluminum (Al), silver (Ag), and an aluminum-silicon alloy (Al—Si alloy). The joint device 21 can join metals of the same type and metals of different types to each other.

A sensor that detects the amount of infrared radiation from the laser irradiated region 15a of the wiring member 15 or the amount of the laser light L reflected therefrom may be adopted in place of the temperature sensor 26. The amount of infrared radiation and the amount of the laser light L reflected (the amount of the laser light L absorbed) are correlated with the surface temperature of the wiring member 15. Therefore, the temperature of the joint interface Sb can be estimated based on the amount of infrared radiation from the laser irradiated region 15a and the amount of the laser light L reflected therefrom. Alternatively, a temperature sensor of a contact type may be used in place of the temperature sensor 26 of the non-contact type. The temperature sensor of the contact type may be provided on a contact surface of the regulation member 23 with the wiring member 15, or provided so as to contact the wiring member 15 when the regulation member 23 is brought closer to the wiring member 15, for example. Alternatively, the temperature sensor of the contact type may be provided on the substrate 12. Examples of the temperature sensor of the contact type include a thermocouple.

A pressure sensor may be used in place of the temperature sensor 26. The pressure sensor detects the pressure due to thermal expansion of the wiring member 15. The controller 27 stores the relationship between the pressure (pressurization force) due to thermal expansion of the wiring member 15 and the joint rate S in advance, and determines that the joint interface Sb has reached a temperature corresponding to the target joint rate S* when the pressure detected by the pressure sensor has reached a value corresponding to the target joint rate S*.

The drive device 24 may not be provided with a fixing mechanism that fixes the regulation member 23 at the regulation position P2 in the case where the regulation member 23 can be fixed at the regulation position P2 using the friction force of the drive source and a portion of the transfer mechanism that performs contact motion with the drive device 24 stationary, depending on the configuration or the kind (type) of the drive source and the transfer mechanism of the drive device 24.

The thickness of the second portion 32 of the regulation member 23 may be the same as the thickness of the first portion 31, and may be larger than the thickness of the first portion 31. The second portion 32 may alternatively be provided as being charged in the hole 23a of the first portion 31. The hole 23a of the first portion 31 may be shaped so as not to have a tapered surface.

The hole 23a of the first portion 31 of the regulation member 23 may be formed in an appropriate shape such as a circular shape or a rectangular shape. That is, the hole 23a may be formed in any shape as long as the laser light L can pass therethrough. Alternatively, the first portion 31 of the regulation member 23 may be provided with a notch (a portion to be removed) in place of the hole 23a. The notch is provided to extend from a side edge of the first portion 31 of the regulation member 23 to a portion (e.g. the middle portion of the regulation member 23) corresponding to the radiation path for the laser light L, for example. The shape of the second portion 32, which is a portion of the regulation member 23 that transmits the laser light L, is set in accordance with the shape of the hole 23a or the notch.

The regulation member 23 may be configured as follows. For example, the first portion 31 is composed of a plurality of (e.g. two) members disposed at intervals. In this case, the second portion 32 is provided in such a manner as to fill the gap between the members as the first portion 31. The laser light L is irradiated to the surface (laser irradiated region 15a) of the surface electrode 14 through the second portion 32 that is provided in the gap between the two members as the first portion 31.

The entirety of the regulation member 23, rather than a part of the regulation member 23, may be formed from a material that transmits the laser light L. In this case, the regulation member 23 is not sectioned into the first portion 31 and the second portion 32.

The regulation member 23 may not be formed in a flat plate shape. For example, the first portion 31 of the regulation member 23 may be formed in a tubular shape. In this case, the second portion 32 is provided in such a manner as to block an opening portion, on the wiring member 15 side, of the first portion 31 in a tubular shape. The laser light L passes through the inside of the first portion 31 in a tubular shape and transmits the second portion 32 to be radiated to the surface of the wiring member 15.

As illustrated in FIG. 8, only the first portion 31 may be provided as the regulation member 23. The second portion 32 in a flat plate shape as the transparent portion is provided separately from the first portion 31. When manufacturing the semiconductor module 11, the second portion 32 is interposed between the wiring member 15 and the first portion 31. The size of the second portion 32 is set to at least a size that is enough to cover and block an opening portion of the hole 23a on the placement surface 22a side (lower side in FIG. 2). The laser light L passes through the hole 23a of the first portion (regulation member 23) and transmits the second portion 32 to be radiated to the laser irradiated region 15a on the surface of the wiring member 15. Also in this manner, movement of the surface electrode 14 and the wiring member 15 in directions (direction of superposition) away from each other can be regulated without obstructing irradiation of the wiring member 15 with the laser light L. In addition, deformation (a warp) of the portion corresponding to the laser irradiated region 15a of the wiring member 15 toward the opposite side from the surface electrode 14 can be regulated by the second portion 32. The second portion 32 may be fixed or may not be fixed to the lower surface (a surface on the placement surface 22a side) of the first portion 31. The second portion 32 as a separate member may also be considered as an element that constitutes the regulation member 23 together with the first portion 31.

The joint device 21 may pressurize the joint interface Sb between the surface electrode 14 and the wiring member 15 from the outside of the wiring member 15 via the regulation member 23 when the surface electrode 14 and the wiring member 15 are to be joined to each other through solid phase diffusion welding. In this case, the joint device 21 is provided with a pressurization device that pressurizes the joint interface Sb from the outside of the wiring member 15, in place of or in addition to the drive device 24. In the case where the pressurization device is provided, the first portion 31 of the regulation member 23 may be provided as a pressurization nozzle in a tubular shape. In this case, the second portion 32 is provided in such a manner as to block an opening portion, on the wiring member 15 side, of the pressurization nozzle. The laser light L that passes through the inside of the pressurization nozzle transmits the second portion 32 to be radiated to the surface of the wiring member 15.

An electron beam radiation device that radiates an electron beam may be adopted, in place of the laser device 25, as a heating device that applies heat for causing solid phase diffusion at the joint interface Sb between the surface electrode 14 and the wiring member 15.

What is claimed is:

1. A joint device comprising:
a regulation device that includes a support base that includes a placement surface on which two metal members superposed on each other are placed, and a regulation member configured to regulate motion of the two metal members in a direction in which the two metal members are superposed on each other with the two metal members held between the placement surface and the regulation member;
a heating device configured to apply heat for causing solid phase diffusion at a joint interface between the two metal members by radiating an electromagnetic beam to a beam irradiated region via the regulation member, the beam irradiated region being set on a surface of one of the two metal members that is farther from the placement surface while the regulation device regulates the motion of the two metal members; and
a transparent portion provided at least at a portion corresponding to the beam irradiated region of the metal member to which the electromagnetic beam is irradiated, to transmit the electromagnetic beam.

2. The joint device according to claim 1, wherein the regulation device is configured to regulate the motion of the two metal members in the direction in which the two metal members are superposed on each other without pressing the superposed two metal members against each other.

3. The joint device according to claim 1, wherein:
the regulation member includes a first portion and a second portion;
the first portion contacts a peripheral edge portion of the beam irradiated region on the surface of the one of the two metal members that is farther from the placement surface; and
the second portion is the transparent portion, and contacts the beam irradiated region on the surface of the one of the two metal members that is farther from the placement surface.

4. The joint device according to claim 1, wherein the heating device is configured to radiate a laser beam or an electron beam as the electromagnetic beam.

5. The joint device according to claim 1, wherein the two metal members are a surface electrode of a semiconductor element provided on a substrate, or a metal film provided on a surface of the substrate, and a wiring member.

6. The joint device according to claim 1, wherein the two metal members are a semiconductor element provided on a substrate and a heat radiation member.

7. The joint device according to claim 1, further comprising:
a detector configured to detect a state of the transparent portion; and
a controller configured to execute protection control determined in order to protect the transparent portion when it is determined that there is a possibility that an abnormality occurs in the transparent portion based on the state of the transparent portion detected through the detector.

8. The joint device according to claim 7, wherein:
the detector is a temperature sensor that detects a temperature of the beam irradiated region of the metal member to which the electromagnetic beam is irradiated, or in a vicinity of the beam irradiated region; and
the controller is configured to lower an output of the heating device compared to a previous output of the heating device, or temporarily stop the output, as the protection control when it is determined that there is a possibility that an abnormality occurs in the transparent portion based on the temperature of the beam irradiated region, or in the vicinity of the beam irradiated region, and the temperature is detected through the temperature sensor.

9. The joint device according to claim 7, wherein:
the detector is a pressure sensor provided in the support base at a position corresponding to the beam irradiated region of the metal member to which the electromagnetic beam is irradiated, and configured to detect a pressure in a direction that crosses the placement surface; and
the controller is configured to lower an output of the heating device compared to a previous output of the heating device, or temporarily stop the output, as the protection control when it is determined that there is a possibility that an abnormality occurs in the transparent portion based on the pressure detected through the pressure sensor.

10. A control method for a joint device,
the joint device including: a regulation device that includes a support base that includes a placement surface on which two metal members superposed on each other are placed, and a regulation member configured to regulate motion of the two metal members in a direction in which the two metal members are superposed on each other with the two metal members held between the placement surface and the regulation member; a heating device configured to apply heat for causing solid phase diffusion at a joint interface between the two metal members by radiating an electromagnetic beam to a beam irradiated region via the regulation member, the beam irradiated region being set on a surface of one of the two metal members that is farther from the placement surface while the regulation device regulates the motion of the two metal members; a transparent portion provided at least at a portion corresponding to the beam irradiated region of the metal member to which the electromagnetic beam is irradiated, to transmit the electromagnetic beam; a detector configured to detect a state of the transparent portion; and a controller,
the control method comprising:
determining, by the controller, that there is a possibility that an abnormality occurs in the transparent portion based on the state of the transparent portion detected through the detector; and
executing, by the controller, protection control when the controller determines that there is a possibility that the abnormality occurs, the protection control being determined in order to protect the transparent portion.
